(19) United States
(12) Patent Application Publication
(10) Pub. No.: US 2008/0241574 A1
(43) Pub. Date: Oct. 2, 2008

(54) SEMICONDUCTOR DEVICE HAVING STRUCTURE WITH SUB-LITHOGRAPHY DIMENSIONS

(75) Inventor: Witold P. Maszara, Morgan Hill, CA (US)

Correspondence Address: FARJAMI & FARJAMI LLP, 26522 LA ALAMEDA AVENUE, SUITE 360, MISSION VIEJO, CA, 92691, US

(73) Assignee: ADVANCED MICRO DEVICES, INC., Sunnyvale, CA (US)

(21) Appl. No.: 11/691,347

(22) Filed: Mar. 26, 2007

(51) Int. Cl. H01L 29/12; H01L 21/00

(52) U.S. Cl. 428/620; 438/759

(57) ABSTRACT

A method for forming a semiconductor device is provided including processing a wafer having a first layer and a second layer, the second layer is over the first layer, forming a vertical post from a sidewall spacer formed from the second layer, forming a filler over the first layer and surrounding the vertical post, and forming a device layer having a hole by removing the vertical post in the filler.

### CROSS-REFERENCE TO RELATED APPLICATION

The present application contains subject matter related to a concurrently filed U.S. patent application by Witold P. Maszara and Qi Xiang entitled “Semiconductor Device Having Structure With Fractional Dimension of the Minimum Dimension of a Lithography System”. The related application is assigned to Advanced Micro Devices, Inc. and is identified by docket number 1000-312.

### TECHNICAL FIELD

The present invention relates generally to semiconductor device, and more particularly to a semiconductor device having structural fractional pitch of the minimum pitch of a lithography system.

### BACKGROUND ART

Modern electronics, such as smart phones, personal digital assistants, location based services devices, digital cameras, music players, servers, and storage arrays, are packing more semiconductor devices into an ever-shrinking physical space with expectations for decreasing cost. One cornerstone for devices to continue proliferation into everyday life is the integration of more functions into a given area of the semiconductor device. Numerous technologies have been developed to meet these requirements.

One approach to increase the density in a semiconductor device involves a technology to transform and shrink images onto a wafer. This process is called lithography or photolithography. Lithography systems have limitations of how small images may be reduced onto a wafer and these limitations bound the minimum dimensions of the semiconductor device. Some examples of the minimum dimensions for the semiconductor device are minimum gate length, structure width, or spacing between structures.

Various types of lithography systems, such as proximity lithography, contact lithography, projection lithography, or immersion lithography, have been used to increase density in a semiconductor device. Each has their advantages and drawbacks but all have minimum dimension limitations as discussed above.

Lithography systems use a light source to transfer an image from a mask to a wafer. Different light sources, such as a ultra-violet light of different wavelengths, different mask technologies, or both to improve the density in a semiconductor device. Again, each approach has their advantages and drawbacks but all have minimum dimension limitations as discussed above

Thus, a need still remains for a semiconductor device providing increased density beyond the limitations of the lithography system, improved yields, lower cost, and increased use of existing manufacturing equipments. In view of the ever-increasing need to save costs and improve efficiencies, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method for forming a semiconductor device including processing a wafer having a first layer and a second layer, the second layer is over the first layer, forming a vertical post from a sidewall spacer formed from the second layer, forming a filler over the first layer and surrounding the vertical post, and forming a device layer having a hole by removing the vertical post in the filler.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is an isometric view of a portion of a semiconductor device in an embodiment of the present invention;

FIG. 2 is an isometric view of a portion of a wafer in an embodiment of the present invention;

FIG. 3 is the structure of FIG. 2 in a sidewall formation phase;

FIG. 4 is the structure of FIG. 3 in a spacer formation phase;

FIG. 5 is the structure of FIG. 4 in a mask phase;

FIG. 6 is the structure of FIG. 5 in an etch phase;

FIG. 7 is the structure of FIG. 6 in a mask removal phase;

FIG. 8 is the structure of FIG. 7 in a coating phase;

FIG. 9 is the structure of FIG. 8 in a hole formation phase;

FIGS. 10A, 10B, and 10C are schematic views of examples of electronics systems in which various aspects of the present invention may be implemented; and

FIG. 11 is a flow chart of a method for manufacture of the semiconductor device in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention. Likewise, the drawings showing embodiments of the system are semi-diagrammatic and not to scale and, particularly, some of the dimensions are for the clarity of presentation and are shown greatly exaggerated in the drawing figures. In addition, where multiple embodiments are disclosed and described having some features in common, for clarity and ease of illustration, description, and comprehension thereof, similar and like features one to another will ordinarily be described with like reference numerals.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

For expository purposes, the term “horizontal” as used herein is defined as a plane parallel to the conventional semiconductor device surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material or photoresist, patterning, exposure, development, etching, cleaning, and/or removal of the material or photoresist as required in forming a described structure. The term “system” as used herein means and refers to the method and to the apparatus of the present invention in accordance with the context in which the term is used.

Semiconductor manufacturing typically involves lithography systems (not shown) or also referred to as photolithography systems (not shown). Some examples of lithography systems are proximity lithography, contact lithography, projection lithography, or immersion lithography. The lithography systems use a light source (not shown) to transfer patterns (not shown) from a mask (not shown) onto a semiconductor wafer. The patterns from the mask may include parallel structures or adjacent structures. Structures formed with lithography systems are characterized by developing the target material. The developing includes forming structures with reticles and selective removal of these structures through etching, not through lasing or burning.

The term “pitch” as used herein refers to a measure between the parallel structures or the adjacent structures of the semiconductor wafer transferred by the lithography system used for the manufacture the semiconductor device. The pitch may be measured from side to side of the same side of the adjacent or parallel structures. The term “minimum pitch” as used herein refers to the minimum pitch value that may be achieved by the lithography system used for the manufacture the semiconductor device.

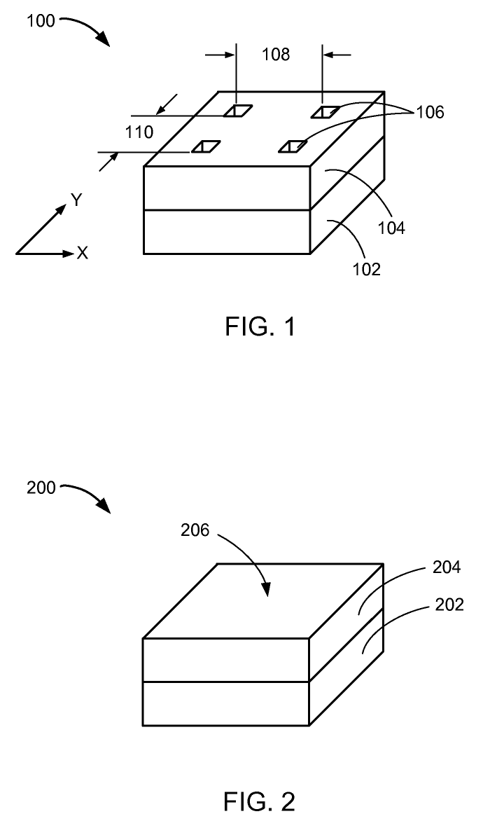

Referring now to FIG. 1, therein is shown an isometric view of a portion of a semiconductor device 100 in an embodiment of the present invention. The portion of the semiconductor device 100, such as a semiconductor die, an integrated circuit die, or a device having a microelectromechanical system (MEMS), includes a first device layer 102 below a second device layer 104 having holes 106.

The first device layer 102, such as a semiconductor substrate, a redistribution layer, a portion of a circuit element, a portion of an optical device, or a portion of a MEMS element, may represent any number of layers of the semiconductor device 100. The holes 106 may be a portion of any number of layers of the semiconductor device 100. The second device layer 104 may be comprised of an electrically conductive material, such as a metal, an electrically nonconductive material, such as a dielectric, or a reflective material, such as a material system providing optical reflective properties. The second device layer 104 may also be comprised of an optically nonreflective material for collimating optical emission through the holes 106.

The holes 106 may be used as a portion of a circuit element, a portion of a MEMS element, a portion of an optical device, a portion of a redistribution structure, or isolation structures. For example, the holes 106 may be filled with an electrically conductive material, such as a metal, forming contacts, electrical vias, or portions of a circuit element. Another example, the holes 106 may be filled with an electrically nonconductive material, such as a dielectric, forming spacers or isolation structures. Yet another example, the holes 106 may provide fit registration for MEMS devices. Yet again another example, the holes 106 may function as optical apertures.

The holes 106 are shown substantially along an x-axis and a y-axis. The holes 106 along the x-axis have a first pitch 108. The first pitch 108 may have a value in a range from a fraction of the minimum pitch, such as a quarter of the minimum pitch, to the minimum pitch or a predetermined pitch greater than the minimum pitch as required by the design of the semiconductor device 100. The holes 106 along the y-axis have a second pitch 110. The second pitch 110 may have a value in a range from a fraction of the minimum pitch, such as a quarter of the minimum pitch, to the minimum pitch or a predetermined pitch greater than the minimum pitch as required by the design of the semiconductor device 100.

For illustrative purposes, the holes 106 along the x-axis and the y-axis have the first pitch 108 and the second pitch 110, respectively, although it is understood that the holes 106 along both axes may have substantially the same pitch or different pitches. Also for illustrative purposes, the holes 106 are shown substantially the same, although it is understood that the holes 106 may be different. Further for illustrative purposes, the holes 106 are shown in an array configuration, although it is understood that the configuration of the holes 106 may be in a different configuration. Yet further for illustrative purposes, the holes 106 are shown as having a pitch that is a fraction of the minimum pitch, although it is understood that other structures may have a measure that is a fraction of the minimum pitch, such as a quarter of the minimum pitch.

Referring now to FIG. 2, therein is shown an isometric view of a portion of a wafer 200 in an embodiment of the present invention. The wafer 200 includes a first layer 202, such as a semiconductor substrate, a redistribution layer, a portion of a circuit element, a portion of an optical device, or a portion of a MEMS element, below a second layer 204. The second layer 204 is over an active side 206 of the first layer 202. The first layer 202 may represent the first device layer 102 of FIG. 1.

The first layer 202 may be comprised of an electrically conductive material or an electrically nonconductive material. The second layer 204 may be comprised of a number of different materials, such as polycrystalline silicon (polysilicon). For illustrative purposes, the wafer 200 is shown having the first layer 202 and the second layer 204, although it is understood that the number of layers may differ.

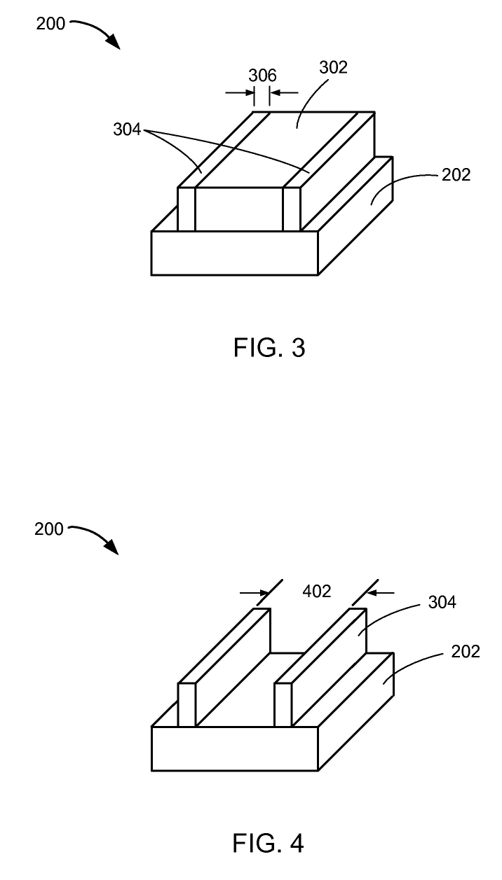

Referring now to FIG. 3, therein is shown the structure of FIG. 2 in a sidewall formation phase. The second layer 204 of FIG. 2 undergoes a patterning process, such as an etch utilizing predetermined patterned photoresist, forming a first strip 302 from the second layer 204 of FIG. 2. For illustrative purposes, the first strip 302 is shown as a single instance, although it is understood that multiple parallel instances of the first strip 302 may be formed. The minimum measure between adjacent instances of the first strip 302 is the minimum pitch.

First sidewall spacers 304, such as spacers of silicon nitride or silicon oxide, are formed along two opposite sides of the first strip 302. The first sidewall spacers 304 may be formed in a number of different processes available to one ordinary skilled in the art. The first sidewall spacers 304 are shown substantially parallel to the y-axis. The first sidewall spacers 304 may be formed with each having a spacer width 306 that is a fraction of the minimum pitch, such as a tenth to a half of the minimum pitch. The first layer 202 is substantially unaffected by the formation of the first strip 302 and the first sidewall spacers 304.

For illustrative purposes, the first sidewall spacers 304 are shown parallel to the y-axis, although it is understood that the first sidewall spacers 304 may be parallel to the x-axis. Also for illustrative purposes, the sides of the first strip 302 is shown as parallel to the x-axis or the y-axis, although it is understood that the first strip 302 may be formed in an angle not parallel to the x-axis or the y-axis. Similarly, the first sidewall spacers 304 may be formed in the same angle as the first strip 302 that is not parallel to the x-axis or the y-axis.

Further for illustrative purposes, the first sidewall spacers 304 are shown on two opposite side of the first strip 302, although it is understood that the first sidewall spacers 304 may be formed on any number of sides of the first strip 302. Yet further for illustrative purposes, the first strip 302 is described as formed with an optical lithography process, although it is understood that the first strip 302 may be one of the sidewall spacers having the minimum pitch.

Referring now to FIG. 4, therein is shown the structure of FIG. 3 in a spacer formation phase. The first strip 302 of FIG. 3 is removed leaving the first sidewall spacers 304 over the first layer 202. The first strip 302 may be removed by a number of different processes available to one ordinary skilled in the art. The first sidewall spacers 304 may have a first pitch 402. The first pitch 402 may have a value in a range from a fraction of the minimum pitch, such as a half of the minimum pitch, to the minimum pitch or a predetermined pitch greater than the minimum pitch as required by the design of the wafer 200. The first sidewall spacers 304 expose portions of the first layer 202 not covered by the first sidewall spacers 304.

For illustrative purposes, the first sidewall spacers 304 are described as having the first pitch 402 with a minimum value of half of the minimum pitch. Although it is understood that the first pitch 402 may have the minimum value of a quarter of the minimum pitch with the first strip 302 of FIG. 1 as one of the sidewall spacers having a pitch of half of the minimum pitch, as described in FIG. 3.

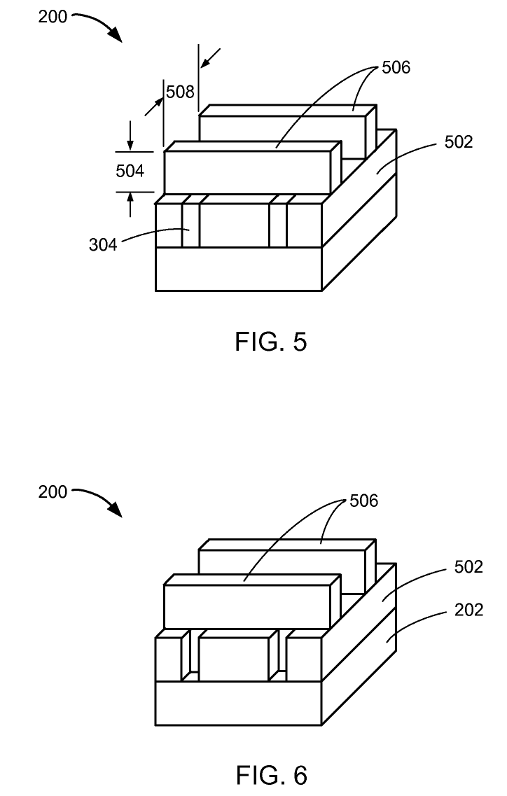

Referring now to FIG. 5, therein is shown the structure of FIG. 4 in a mask phase. A first filler 502, such as an oxide, surrounds the first sidewall spacers 304. The first filler 502 may be applied by a number of different processes available to one ordinary skilled in the art. The first filler 502 and the first sidewall spacers 304 undergo a planarization process, such as a chemical and mechanical planarization (CMP), such that the top surface of the first sidewall spacers 304 and the first filler 502 are coplanar.

A masking structure 504, such as an oxide, is formed over the first sidewall spacers 304 and the first filler 502. The masking structure 504 has parallel structures 506 that intersect the vertical planes of the first sidewall spacers 304. The intersection may be orthogonal to the vertical planes of the first sidewall spacers 304. The parallel structures 506 may have second pitch 508. The second pitch 508 may have a value in the range from a fraction of the minimum pitch, such as a quarter of the minimum pitch, to the minimum pitch or a predetermined pitch greater than the minimum pitch as required by the design of the semiconductor device 100.

The masking structure 504 may be formed by a number of different processes available to one ordinary skilled in the art. For example, the parallel structures 506 may be formed by a conventional lithography image transfer such that the minimum value of the second pitch 508 is the minimum pitch. The parallel structures 506 may be alternatively formed by a process similar to forming the first sidewall spacers 304 of FIG. 4 such that the parallel structures 506 are sidewall spacers and the minimum value of the second pitch 508 is a quarter of the minimum pitch.

Referring now to FIG. 6, therein is shown the structure of FIG. 5 in an etch phase. The structure of FIG. 5 undergoes an etch process, such as a selective anisotropic etch, removing portions of the first sidewall spacers 304 of FIG. 5 not covered by the parallel structures 506. The etch process exposes the first layer 202 in the opening of the first filler 502.

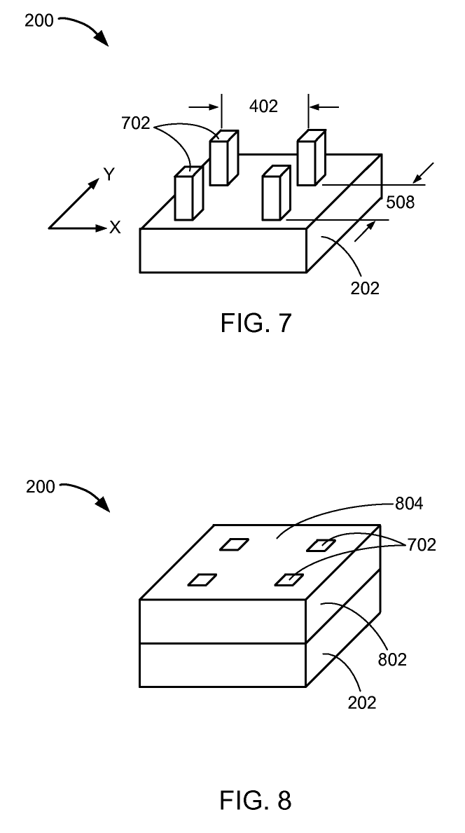

Referring now to FIG. 7, therein is shown the structure of FIG. 6 in a mask removal phase. The parallel structures 506 of FIG. 6 and the first filler 502 of FIG. 6 are removed exposing vertical posts 702 over the first layer 202. The first pitch 402 and the second pitch 508 of the vertical posts 702 may represent the first pitch 108 of FIG. 1 and the second pitch 110 of FIG. 1, respectively.

Referring now to FIG. 8, therein is shown the structure of FIG. 7 in a coating phase. A second filler 802, such as an electrically conductive material, an electrically nonconductive material, or an optical material, is applied over the first layer 202 and surrounding the vertical posts 702. The second filler 802 may be applied by a number of different processes, such as spin coating.

The second filler 802 and the vertical posts 702 may optionally undergo a planarization process, such as a chemical and mechanical planarization (CMP), such that the top surface of vertical posts 702 and the second filler 802 are coplanar. The second filler 802 exposes the vertical posts 702.

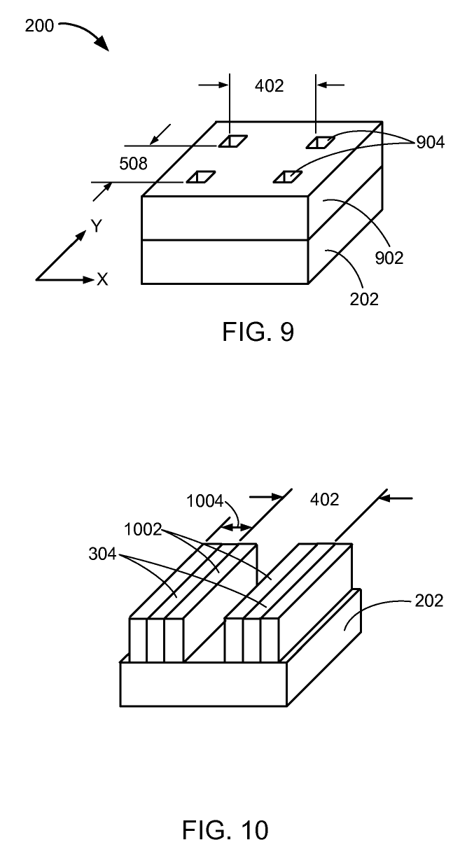

Referring now to FIG. 9, therein is shown the structure of FIG. 8 in a hole formation phase. The structure of FIG. 8 undergoes a removal process to remove the vertical posts 702 of FIG. 8 forming a second device layer 902 and holes 904 in the second device layer 902. The vertical posts 702 may be removed such that the holes 904 expose the first layer 202. Alternatively, the vertical posts 702 may be partially removed forming the holes 904 without exposing the first layer 202.

The holes 904 may represent the holes 106 of FIG. 1. The first pitch 402 and the second pitch 508 of the holes 904 may represent the first pitch 108 of FIG. 1 and the second pitch 110 of FIG. 1, respectively. Each of the holes 904 may have a width in a range about a tenth to half of the minimum pitch similar to the range of the first sidewall spacers 304 of FIG. 3. The structure of FIG. 9 may undergo singulation forming devices, such as the semiconductor device 100 of FIG. 1.

Referring now to FIG. 10, therein is shown the structure of FIG. 4 in a second spacer formation phase. Second sidewall spacers 1002 may be formed along sides of the first sidewall spacers 304 over the first layer 202. The first sidewall spacers 304 have the first pitch 402. The second sidewall spacers 1002 have a second pitch 1004. The second pitch 1004 has a range about a quarter of the minimum pitch to a half of the minimum pitch.

The second sidewall spacers 1002 may be formed by a number different process. For example, a layer (not shown) of a material of the second sidewall spacers 1002 may be applied over the structure of FIG. 4. A photoresist layer (not shown) may be patterned over the layer and the layer may be removed, such as etching, forming the second sidewall spacers 1002 along the sides of the first sidewall spacers 304.

Multiple applications of the photoresist patterning and etching may be performed for forming the second sidewall spacers 1002. For example, the multiple applications may be performed with different reticles (not shown) forming different photoresist patterns and with etching steps. Another example, the same reticle (not shown) may be used with double exposure with the reticle shifted forming the photoresist patterns and with etching steps.

The second sidewall spacers 1002 may be further processed continuing with the phases described in FIG. 5 to FIG. 9 forming the vertical posts 702 of FIG. 7. The vertical posts 702 continued from this phase may have the second pitch 1004 as the first pitch 402 of FIG. 7, the second pitch 508 of FIG. 7, or both.

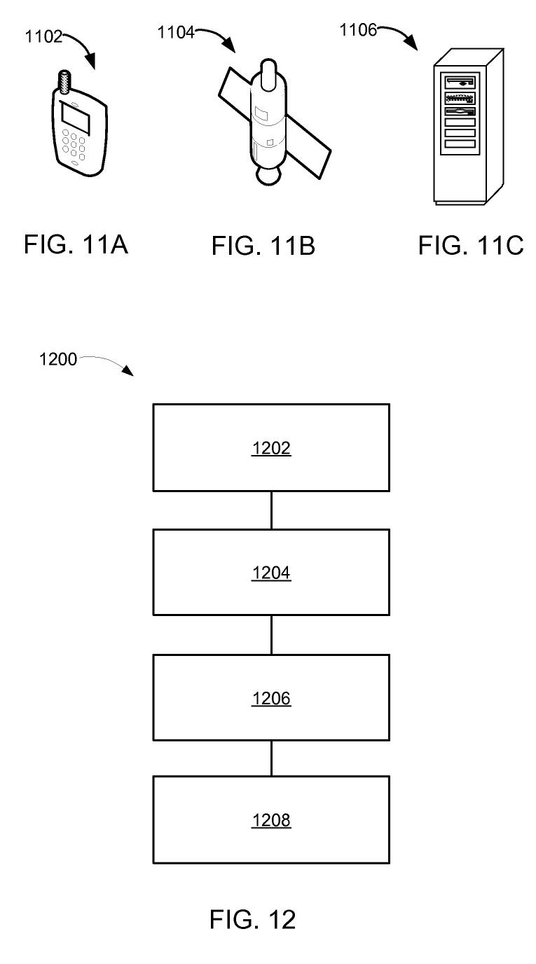

Referring now to FIGS. 11A, 11B, and 11C, therein are shown schematic views of examples of electronics systems in which various aspects of the present invention may be implemented. A smart phone 1102, a satellite 1104, and a compute system 1106 are examples of the electronic systems using the present invention. The electronic systems may be any system that performs any function for the creation, transportation, storage, and consumption of information. For example, the smart phone 1102 may create information by transmitting voice to the satellite 1104. The satellite 1104 is used to transport the information to the compute system 1106. The compute system 1106 may be used to store the information. The smart phone 1102 may also consume information sent from the satellite 1104.

The electronic systems, such as the smart phone 1102, the satellite 1104, and the compute system 1106, include a one or more subsystem, such as a printed circuit board having the present invention or an electronic assembly having the present invention. The electronic system may also include a subsystem, such as an adapter card.

Referring now to FIG. 12, therein is a flow chart of a method 1200 for manufacture of the semiconductor device in an embodiment of the present invention. The method 1200 includes processing a wafer having a first layer and a second layer, the second layer is over the first layer in a block 1202; forming a vertical post from a sidewall spacer formed from the second layer in a block 1204; forming a filler over the first layer and surrounding the vertical post in a block 1206; and forming a device layer having a hole by removing the vertical post in the filler in a block 1208.

It has been discovered that the present invention thus has numerous aspects.

A principle aspect that has been unexpectedly discovered is that the present invention increases densities of structures below the minimum pitch capability of the lithography system used to manufacture a semiconductor device. The structures, such as micropillars, having the pitch that is a fraction of the minimum pitch, such as a quarter of the minimum pitch, may be used to form holes of the same pitch. The material forming the holes as well as the material that may used to fill the holes may be used in numerous applications, such as in integrated circuits, MEMS, or optical applications.

Another aspect is that the present invention uses the micropillars to form a device layer and holes in the device layer that may be formed in any layer of the semiconductor device.

Yet another aspect of the present invention use the device layer and the holes in the device layer may be filled to form contacts, electrical vias, isolation structures, registration holes for MEMS elements, portions of circuit elements, or apertures for optical devices.

Yet another aspect is that the present invention provides the method for the manufacture of devices of different structures of varying sizes, configurations, and stacking options.

Yet another aspect is that the present invention provides reuse of existing and mature lithography systems while providing increased integration and density.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the semiconductor system of the present invention furnishes important and heretofore unknown and unavailable solutions, capabilities, and functional aspects for increased density, improved yield, and lowered cost. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method for forming a semiconductor device comprising:
processing a wafer having a first layer and a second layer, the second layer is over the first layer;
forming a vertical post with a sidewall spacer formed from the second layer;
forming a filler over the first layer and surrounding the vertical post; and
forming a device layer having a hole by removing the vertical post in the filler.

2. The method as claimed in claim 1 wherein forming the vertical post from the sidewall spacer formed from the second layer includes:
forming the sidewall spacer from the second layer;
forming a masking structure over and intersecting the sidewall spacer; and
forming the vertical post from the sidewall spacer below the masking structure.

3. The method as claimed in claim 1 wherein:
forming the vertical post includes:
forming the vertical post having a width in a range about half of a minimum pitch to a tenth of the minimum pitch; and
forming the device layer having the hole also includes:
forming the hole having the width in the device layer.

4. The method as claimed in claim 1 wherein:
forming the vertical post includes:
forming vertical posts, having a pitch that is a fraction of a minimum pitch between the minimum pitch to a half of the minimum pitch, from the second layer; and
forming the device layer the hole also includes:
forming holes having the pitch in the device layer.

5. The method as claimed in claim 1 further comprising forming an electronic system or a subsystem with the semiconductor device.

6. A method for forming a semiconductor device comprising:
processing a wafer having a first layer and a second layer, the second layer is over the first layer;
forming vertical posts from sidewall spacers formed from the second layer includes:
forming the sidewall spacers from the second layer,
forming parallel structures over and intersecting the sidewall spacers, and
forming the vertical posts from the sidewall spacers below the parallel structures;
forming a filler over the first layer and surrounding the vertical posts;
planarizing the filler and the vertical posts; and
forming a device layer having holes by removing the vertical posts in the filler.

7. The method as claimed in claim 6 wherein planarizing the filler and the vertical posts includes exposing the vertical posts.

8. The method as claimed in claim 6 wherein removing the vertical posts for forming the holes includes exposing the first layer through the holes.

9. The method as claimed in claim 6 wherein forming the device layer having the holes by removing the vertical posts includes etching the vertical posts.

10. The method as claimed in claim 6 wherein:
forming the vertical posts includes:
forming a first sidewall spacer from the second layer;
forming second sidewall spacers along the first sidewall spacer;
forming the parallel structures over and intersecting the second sidewall spacers;
forming the vertical posts from the second sidewall spacers below the parallel structures; and
forming the device layer having the holes also includes:
forming the holes having a pitch that is a fraction of a minimum pitch between a quarter of the minimum pitch and a half of the minimum pitch.

11. A semiconductor device comprising:
a semiconductor die having a first device layer and a second device layer, the second device layer has a hole with a width in a range about a half of a minimum pitch to a tenth of the minimum pitch and is over the first device layer, the second device layer having the hole has a characteristic of being formed by lithography etching.

12. The device as claimed in claim 11 wherein the second device layer having the hole has holes having a pitch that is a fraction of the minimum pitch between the minimum pitch and a quarter of the minimum pitch.

13. The device as claimed in claim 11 wherein the hole has an electrically conductive material.

14. The device as claimed in claim 11 wherein the hole has an electrically nonconductive material.

15. The device as claimed in claim 11 further comprising an electronic system or a subsystem with the semiconductor device.

16. The device as claimed in claim 11 wherein the second device layer having the hole is part of an active side of the semiconductor die.

17. The device as claimed in claim 16 wherein the second device layer with the hole exposes the first device layer.

18. The device as claimed in claim 16 wherein the hole is a portion of a mechanical system.

19. The method as claimed in claim 16 wherein the hole has an optical transmitting material for forming optical apertures in the second device layer.

20. The device as claimed in claim 16 wherein the hole is a portion of a microelectromechanical system.
